(19) United States
(12) Patent Application Publication
(10) Pub. No.: US 2026/0092974 A1
(43) Pub. Date: Apr. 2, 2026

(54) SECONDARY BATTERY STATE ESTIMATION SYSTEM, SECONDARY BATTERY STATE ESTIMATION METHOD, AND PROGRAM

(71) Applicant: HONDA MOTOR CO., LTD., Tokyo (JP)

(72) Inventors: Takuma Kawahara, Wako-shi (JP); Yuki sato, Utsunomiya-shi (JP)

(21) Appl. No.: 19/294,352

(22) Filed: Aug. 8, 2025

(30) Foreign Application Priority Data
Sep. 30, 2024 (JP) 2024-171830

(51) Int. Cl. G01R 31/367; G01R 31/36; G01R 31/388; G01R 31/392

(52) U.S. Cl. CPC G01R 31/367; G01R 31/3648; G01R 31/388; G01R 31/392

(57) ABSTRACT

A system including a secondary battery state estimation device includes an OCV estimation portion that acquires a machine learning model and estimates the open circuit voltage by the machine learning model. The OCV estimation portion acquires first data having data in a time series of the current, the closed circuit voltage, and the open circuit voltage of a secondary battery in a predetermined state including at least one of charging and discharging. The OCV estimation portion acquires the machine learning model that outputs an overvoltage of the secondary battery at an arbitrary time based on the first data. The OCV estimation portion inputs second data having data of the current and the closed circuit voltage at a predetermined time detected in a secondary battery to be estimated to the machine learning model and thereby estimates an overvoltage of the secondary battery to be estimated at an arbitrary time.

### CROSS-REFERENCE TO RELATED APPLICATION

Priority is claimed on Japanese Patent Application No. 2024-171830, filed on September 30, 2024, the contents of which are incorporated herein by reference.

### BACKGROUND

### FIELD OF THE INVENTION

The present invention relates to a secondary battery state estimation system, a secondary battery state estimation method, and a program.

### BACKGROUND

In recent years, in order to ensure that more people have access to affordable, reliable, sustainable, and advanced energy, research and development relating to a secondary battery which contributes to energy efficiency has been conducted.

In the related art, for example, a device is known which acquires an OCV (Open Circuit Voltage) curve indicating a change in the open circuit voltage in accordance with a discharge capacity by performing a filtering process on history data of the closed circuit voltage (CCV) of a battery (for example, refer to PCT International Publication No. WO 2023/054443). The device extracts data which can be regarded as the open circuit voltage from the history data of the closed circuit voltage, for example, by the filtering process based on a predetermined condition relating to the current, the voltage, the temperature, and the like of the battery.

### SUMMARY

In a technique relating to a secondary battery, it is a problem to prevent a decrease in an estimation accuracy of an internal state including an OCV curve or the like, for example, even when the secondary battery is degraded. For example, in the device of the conventional technique described above, when an overvoltage increases in association with an increase in an internal resistance due to the degradation of the secondary battery, there is a possibility that the estimation accuracy of the open circuit voltage (OCV) is decrease.

Further, for example, even when the open circuit voltage (OCV) is estimated based on an electrochemical model that estimates the internal resistance, a correspondence relationship between a discharge capacity and the open circuit voltage (OCV) at the time of starting of discharging, or the like, there is a possibility that the estimation accuracy of the open circuit voltage (OCV) is decreased in association with the increase in the internal resistance due to the degradation of the secondary battery.

An aspect of the present invention aims at achieving prevention of a decrease in an estimation accuracy of an internal state of a secondary battery.

A secondary battery state estimation system according to a first aspect of the present invention includes: a learning model that is structured so as to acquire first data having data in a time series of the current, the closed circuit voltage, and the open circuit voltage of a secondary battery in a predetermined state including at least one of charging and discharging and to output an open circuit voltage or an overvoltage which is a difference between the open circuit voltage and the closed circuit voltage of the secondary battery at an arbitrary time based on the first data; and a voltage estimation portion that inputs second data having data of the current and the closed circuit voltage at a predetermined time detected in a secondary battery to be estimated to the learning model and thereby estimates the open circuit voltage or an overvoltage of the secondary battery to be estimated at an arbitrary time.

A second aspect is the secondary battery state estimation system according to the first aspect described above, wherein the second data may have data in a time series of the current and the closed circuit voltage detected in the secondary battery to be estimated.

A third aspect is the secondary battery state estimation system according to the second aspect described above, wherein the voltage estimation portion may input previous zone data having data of the current and the closed circuit voltage in a predetermined previous time zone before a predetermined time detected in the secondary battery to be estimated to the learning model and thereby estimate the open circuit voltage or an overvoltage of the secondary battery to be estimated at the predetermined time.

A fourth aspect is the secondary battery state estimation system according to the second or third aspect described above, wherein the voltage estimation portion may input subsequent zone data having data of the current and the closed circuit voltage in a predetermined subsequent time zone after a predetermined time detected in the secondary battery to be estimated to the learning model and thereby estimate the open circuit voltage or an overvoltage of the secondary battery to be estimated at the predetermined time.

A fifth aspect is the secondary battery state estimation system according to the first or second aspect described above, wherein the second data may not have data relating to the temperature of the secondary battery to be estimated.

A sixth aspect is the secondary battery state estimation system according to the first or second aspect described above, wherein the learning model may output the overvoltage of the secondary battery.

A seventh aspect is the secondary battery state estimation system according to the first or second aspect described above, wherein the learning model may output the open circuit voltage of the secondary battery.

An eighth aspect is the secondary battery state estimation system according to the first or second aspect described above, wherein the first data may have data in a time series of the current, the closed circuit voltage, and the open circuit voltage of the degraded secondary battery.

A secondary battery state estimation method according to a ninth aspect of the present invention is a method performed by an electronic apparatus including a process portion that estimates the open circuit voltage or an overvoltage of a secondary battery to be estimated, the method including: a model acquisition step of acquiring a learning model that acquires first data having data in a time series of the current, the closed circuit voltage, and the open circuit voltage of a secondary battery in a predetermined state including at least one of charging and discharging and that outputs an open circuit voltage or an overvoltage which is a difference between the open circuit voltage and the closed circuit voltage of the secondary battery at an arbitrary time based on the first data; and a voltage estimation step of inputting second data having data of the current and the closed circuit voltage at a predetermined time detected in the secondary battery to be estimated to the learning model acquired by the model acquisition step and thereby estimating the open circuit voltage or an overvoltage of the secondary battery to be estimated at an arbitrary time.

A tenth aspect of the present invention is a computer-readable non-transitory recording medium that records a program causing a computer of an electronic apparatus including a process portion that estimates the open circuit voltage or an overvoltage of a secondary battery to be estimated to execute: a model acquisition step of acquiring a learning model that acquires first data having data in a time series of the current, the closed circuit voltage, and the open circuit voltage of a secondary battery in a predetermined state including at least one of charging and discharging and that outputs the open circuit voltage or an overvoltage which is a difference between the open circuit voltage and the closed circuit voltage of the secondary battery at an arbitrary time based on the first data; and a voltage estimation step of inputting second data having data of the current and the closed circuit voltage at a predetermined time detected in the secondary battery to be estimated to the learning model acquired by the model acquisition step and thereby estimating the open circuit voltage or an overvoltage of the secondary battery to be estimated at an arbitrary time.

According to the first aspect described above, by using the learning model that outputs the open circuit voltage or the overvoltage in accordance with the input of the data of the current and the closed circuit voltage, it is possible to prevent the decrease in the estimation accuracy of the internal state of the secondary battery.

In the case of the second aspect described above, the second data has the data in a time series, and thereby, it is possible to improve the estimation accuracy of the open circuit voltage by the learning model.

In the case of the third aspect described above, it is possible to estimate the open circuit voltage by past data before the target time, and it is possible to improve the versatility of the learning model.

In the case of the fourth aspect described above, it is possible to estimate the open circuit voltage by future data after the target time, and it is possible to improve the versatility of the learning model.

In the case of the fifth aspect described above, it is possible to estimate the open circuit voltage without requiring the data of the temperature, and, for example, even when the learning model is acquired only by the data before degradation of the secondary battery, it is possible to improve the estimation accuracy of the open circuit voltage with respect to the secondary battery after degradation.

In the case of the sixth or seventh aspect described above, it is possible to easily estimate the open circuit voltage of the secondary battery with high accuracy.

According to the eighth or ninth aspect described above, by using the learning model that outputs the open circuit voltage or the overvoltage in response to the input of the data of the current and the closed circuit voltage, it is possible to prevent the decrease in the estimation accuracy of the internal state of the secondary battery.

### BRIEF DESCRIPTION OF THE DRAWINGS

FIG. 1 is a block diagram showing the functional configuration of a system including a secondary battery state estimation device in an embodiment of the present invention.

FIG. 2 is a view showing an example of a flow of information in a process by an estimation portion of the secondary battery state estimation device in the embodiment of the present invention.

FIG. 3 is a view showing an example of a correspondence relationship between the open circuit voltage (OCV) and the closed circuit voltage (CCV) acquired by the estimation portion of the secondary battery state estimation device in the embodiment of the present invention.

FIG. 4 is a view showing an example of an OCV curve acquired based on an OCP curve of each of a positive electrode and a negative electrode by the estimation portion of the secondary battery state estimation device in the embodiment of the present invention.

FIG. 5 is a flowchart showing a process performed by the secondary battery state estimation device in the embodiment of the present invention.

### DESCRIPTION OF EMBODIMENTS

Hereinafter, a secondary battery state estimation system, a secondary battery state estimation method, and a program according to an embodiment of the present invention will be described with reference to the accompanying drawings.

A secondary battery according to an embodiment is, for example, detachably or fixedly arranged in various electric apparatuses.

Examples of various electric apparatuses include an electric vehicle, an electric movable body, an electric machine, an electric power source device, and the like. Examples of the electric vehicle include an electric automobile including a rotary electric machine driven by electric power of a secondary battery as a power source, a saddle riding vehicle, a kick skater, a hybrid vehicle by a combination of a rotary electric machine and an internal combustion engine, a fuel cell vehicle by a combination of a secondary battery and a fuel cell, and the like. Examples of the electric movable body include a robot, a movable work machine, a flying vehicle, a movable body on water, an underwater movable body, and the like. Examples of the electric machine include a construction machine including a rotary electric machine as a power source and the like. Examples of the electric power source device include a stationary or mobile electric power source device that performs discharging and charging of a secondary battery, an exchange device that supplies (provides) and receives a secondary battery for a user in a so-called battery share service, or the like.

Various electric apparatuses may include, for example, an external charging function of being charged by an external electric power source (an external DC electric power source and an external AC electric power source) such as a PHV (Plug-in Hybrid Vehicle) or a PHEV (Plug-in Hybrid Electric Vehicle). Various electric apparatuses may include, for example, a function of supplying electric power to the outside by the electric power of the secondary battery. Further, the rotary electric machine mounted on the electric vehicle may transfer electric power to and from the secondary battery, for example, by a regeneration operation using rotation power input from a wheel side, electric power generation by power input from an internal combustion engine, or the like in addition to a power running operation.

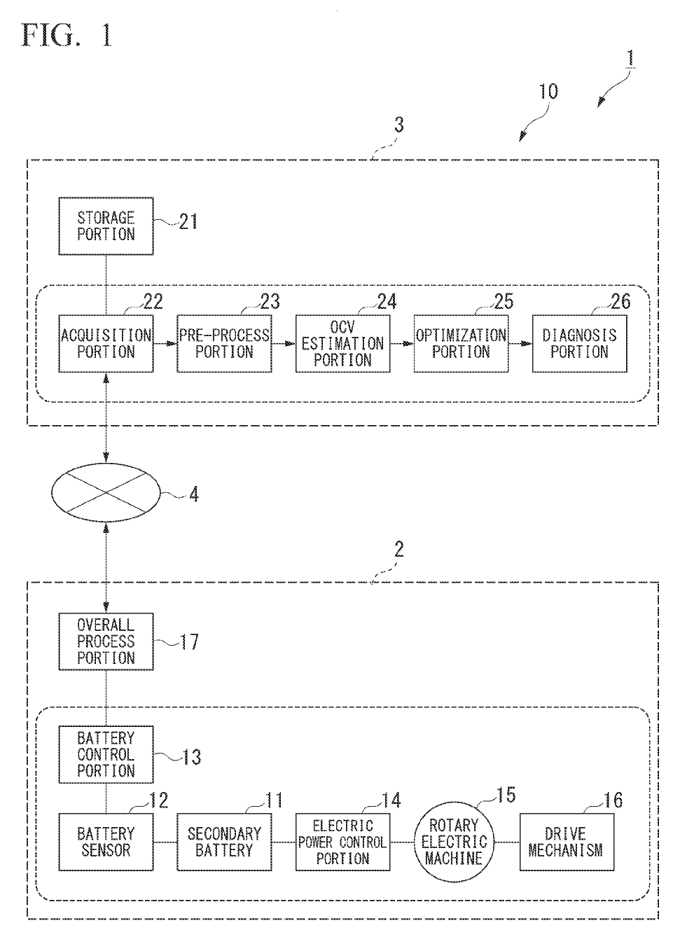

FIG. 1 is a block diagram showing the functional configuration of a system 1 including a secondary battery state estimation device 10 of the embodiment.

As shown in FIG. 1, a system 1 (a secondary battery state estimation system, an electronic apparatus) of the embodiment includes, for example, a vehicle 2 and a server 3. The vehicle 2 and the server 3 are connected to each other, for example, via a wired or wireless communication network (network) 4. Examples of the network 4 include the Internet, a mobile communication network, a LAN (Local Area Network), a WAN (Wide Area Network), and the like. The LAN is, for example, a wired LAN (Local Area Network) of a predetermined standard such as Ethernet or a wireless LAN of various standards such as Wi-Fi and Bluetooth (registered trademark).

The secondary battery state estimation device 10 of the embodiment is constituted, for example, of the server 3.

The vehicle 2 includes, for example, a secondary battery 11, a battery sensor 12, a battery control portion 13, an electric power control portion 14, a rotary electric machine 15, a drive mechanism 16, and an overall process portion 17.

The secondary battery 11 is, for example, a variety of batteries that repeat charging and discharging such as a lithium ion battery, a sodium ion battery, a nickel hydride battery, or the like. The electrolyte of the secondary battery 11 is, for example, a non-aqueous electrolyte such as a liquid, a solid, or a polymer.

A positive electrode active material that constitutes a positive electrode of the secondary battery 11 is, for example, a metal oxide containing lithium ions or the like in the case of a lithium ion battery.

The metal oxide containing lithium ions is, for example, a simple substance of a complex oxide by lithium and a metal such as nickel, cobalt, manganese, and aluminum, a mixture of a plurality of different complex oxides, or the like. The complex oxides are classified into a bedded salt type, a spinel type, and an olivine type, for example, from the viewpoint of a crystal structure. Examples of the complex oxides of the bedded salt type include lithium cobalt oxide (LCO: LiCoO₂), nickel-cobalt-manganese oxide (NCM: Li(NiₓCo_{y}Mn_{z})O₂), nickel-cobalt-aluminum oxide (NCA: LiNiₓCo_{y}AlₓO₂), and the like. Examples of the complex oxides of the spinel type include lithium manganese oxide (LMO: LiMn₂O₄), lithium nickel-manganese oxide (LNMO: LiNiₓMn_{y}O₄), and the like. Examples of the complex oxides of the olivine type include lithium iron phosphate (LFP: LiFePO₄), lithium manganese iron phosphate (LMFP: LiMnₓFe₍₁₋ₓ₎PO₄), and the like.

A negative electrode active material that constitutes a negative electrode of the secondary battery 11 is formed of, for example, a carbon material, an oxide material, a mixed material, or the like in the case of a lithium ion battery. Examples of the carbon material include graphite (black lead), hard carbon (non-graphitizable carbon), and the like. Examples of the oxide material include lithium titanate (LTO: Li₄Ti₅O₁₂) and the like. Examples of the mixed material include a mixed material of a metal material and a carbon material such as Si and Sn and the like, such as a mixed material of graphite and an oxide (SiOₓ) of silicon or the like.

The battery sensor 12 includes, for example, various sensors that detect the state of the secondary battery 11. The battery sensor 12 includes, for example, a voltage sensor, a current sensor, a temperature sensor, and the like. The battery sensor 12 outputs, for example, signals of various detection values of the voltage, the current, the temperature, and the like relating to the state of the secondary battery 11.

The battery control portion 13 is, for example, a so-called BMU (Battery Management Unit) and monitors and controls the state of the secondary battery 11. The battery control portion 13 is, for example, a software function unit that functions by a predetermined program being executed by a processor such as a CPU (Central Processing Unit). The software function unit is an ECU (Electronic Control Unit) including a processor such as a CPU, a ROM (Read Only Memory) that stores a program, a RAM (Random Access Memory) that temporarily stores data, and an electronic circuit such as a timer. At least part of the battery control portion 13 may be an integrated circuit such as an LSI (Large Scale Integration).

The battery control portion 13 stores, for example, information relating to the secondary battery 11, a predetermined program, and the like. The information relating to the secondary battery 11 includes, for example, identification information such as an ID (Identifier) exclusively assigned to the secondary battery 11, the manufacturing date and time, the capacity of an initial state, information relating to the state of the secondary battery 11 based on an output of the battery sensor 12, and the like. The information relating to the state of the secondary battery 11 includes, for example, information relating to the current state such as a charging state such as a charging rate, a remaining capacity (SOC: State Of Charge), or an electric power amount, history of charging and discharging such as the number of times of charging, the voltage, and the temperature, information relating to the current degradation state such as the degree of degradation, information relating to the presence or absence of abnormality, and the like.

The electric power control portion 14 is connected to the secondary battery 11 and the rotary electric machine 15. The electric power control portion 14 includes, for example, a voltage converter such as a DC-DC converter that converts the voltage in DC and an electric power converter such as a DC-AC converter that converts electric power between DC and AC. The electric power control portion 14 controls electric power transfer between the secondary battery 11 and the rotary electric machine 15, for example, based on a control signal received from the overall process portion 17.

The rotary electric machine 15 is, for example, a three-phase AC brushless DC motor or the like. The rotary electric machine 15 generates rotation power by performing a power running operation by electric power that is supplied from the electric power control portion 14. For example, when the rotary electric machine 15 is connected to a wheel of the vehicle 2, the rotary electric machine 15 generates a travel drive force by performing the power running operation by the electric power that is supplied from the electric power control portion 14. The rotary electric machine 15 may generate electric power by performing a regeneration operation by rotation power that is input from the wheel side of the vehicle 2. When the rotary electric machine 15 is connected to an internal combustion engine of the vehicle 2, the rotary electric machine 15 may generate electric power by the power of the internal combustion engine.

The drive mechanism 16 is a power transmission mechanism connected to a rotor of the rotary electric machine 15. The drive mechanism 16 includes, for example, equipment elements such as a gear, a belt, and a chain. The drive mechanism 16 transmits, for example, power between the rotary electric machine 15 and the wheel of the vehicle 2. The drive mechanism 16 may include, for example, a regulation mechanism that regulates power transmission such as an electric parking brake that stops rotation of the wheel or a drive shaft and a parking lock mechanism.

The overall process portion 17 overall controls the operation of the vehicle 2. The overall process portion 17 includes, for example, a software function unit. At least part of the overall process portion 17 may include an integrated circuit.

The overall process portion 17 includes, for example, an input-output section and a communication section.

The input-output section includes, for example, various operation devices such as a keyboard, a touch panel, a mouse, and a button, a display device such as a liquid crystal display or an organic EL (Electro Luminescence) display, and various input-output devices such as a microphone for voice input and a speaker for sound output. The input-output section receives, for example, an operation by an operator such as a user or an input operation which is a voice input and outputs a signal in accordance with the input operation.

The communication section performs transmission and reception of various information to and from the server 3 via the network 4. The communication section transmits to the server 3, for example, information by a combination of information such as date and time, identification information of the vehicle 2 or the secondary battery 11, and information relating to the secondary battery 11 received from the battery control portion 13.

The server 3 includes, for example, a software function unit. At least part of the overall process portion 17 may include an integrated circuit. The server 3 includes, for example, a storage portion 21, an acquisition portion 22, a pre-process portion 23, an OCV estimation portion 24 (voltage estimation portion, process portion), an optimization portion 25, and a diagnosis portion 26.

The storage portion 21 stores, for example, various information such as information relating to the secondary battery 11 acquired by the server 3 in advance or received by the server 3 from the vehicle 2 at an appropriate timing and information generated by the server 3, and a predetermined program.

The acquisition portion 22 acquires, for example, time series data of the voltage, the current, the temperature, and the like of the secondary battery 11 from the vehicle 2. The voltage of the secondary battery 11 is, for example, the closed circuit voltage (CCV). The acquisition portion 22 acquires a discharge capacity (discharge amount), for example, by integrating the time series data of the current.

The pre-process portion 23 performs, for example, a process such as cleansing and filtering of the time series data acquired by the acquisition portion 22. The pre-process portion 23 excludes, for example, data in which a loss, an abnormality, or the like occurs from the time series data.

The OCV estimation portion 24 performs, for example, acquisition of a machine learning model and estimation of the open circuit voltage (OCV) using the machine learning model. The OCV estimation portion 24 acquires the machine learning model, for example, based on a test performed on the secondary battery 11 in which the degradation state is known, a simulation performed on a predetermined model of the secondary battery 11, or the like. The OCV estimation portion 24 acquires time series data (first data) of the current, the closed circuit voltage (CCV), and the open circuit voltage (OCV) of the secondary battery 11 in a predetermined state including at least one of charging and discharging, for example, by the test or the simulation. The OCV estimation portion 24 acquires a machine learning model that outputs an overvoltage (that is, the difference between the open circuit voltage and the closed circuit voltage) of the secondary battery 11 at an arbitrary time with respect to an input of data (second data) of the current and the closed circuit voltage (CCV) at an appropriate time, for example, based on the acquired time series data. The machine learning model is, for example, a regression model such as a random forest, a support vector machine, and a neural network.

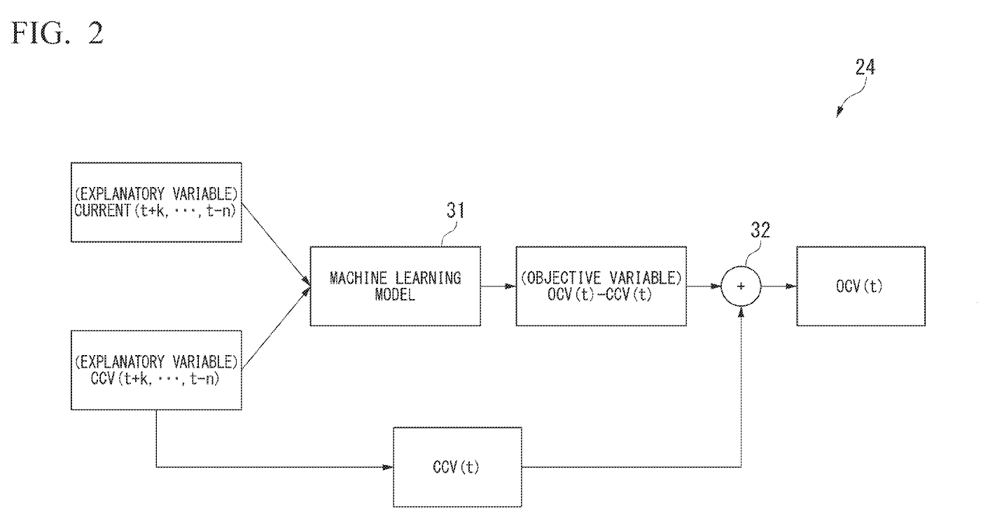

FIG. 2 is a view showing an example of a flow of information in a process by the OCV estimation portion 24 of the secondary battery state estimation device 10 of the embodiment.

As shown in FIG. 2, the OCV estimation portion 24 includes, for example, an overvoltage output section 31 and the open circuit voltage (OCV) calculation section 32.

The overvoltage output section 31 outputs an overvoltage at a predetermined time t which is an objective variable with respect to an input of the data of the current and the closed circuit voltage (CCV) at an appropriate time which is an explanatory variable, for example, by a machine learning model acquired in advance. For example, the data of the current and the closed circuit voltage (CCV) includes data at a predetermined time t which is a target and data (at least one of previous zone data and subsequent zone data) at one or more times of a predetermined first time zone (predetermined previous time zone) before the predetermined time t and a predetermined second time zone (predetermined subsequent time zone) after the predetermined time t. The predetermined first time zone is, for example, a time zone from a time (t - n) by an arbitrary time n to the predetermined time t or the like. The predetermined second time zone is, for example, a time zone from the predetermined time t to a time (t + k) by an arbitrary time k or the like. The overvoltage at the predetermined time t is, for example, a difference (= (OCV (t) - CCV (t)) between the open circuit voltage (OCV (t)) and the closed circuit voltage (CCV (t)) at the predetermined time t.

The open circuit voltage (OCV) calculation section 32 outputs the open circuit voltage (OCV (t)) at the predetermined time t, for example, by adding the overvoltage at the predetermined time t output from the overvoltage output section 31 and the closed circuit voltage (CCV (t)) at the predetermined time t which is the explanatory variable.

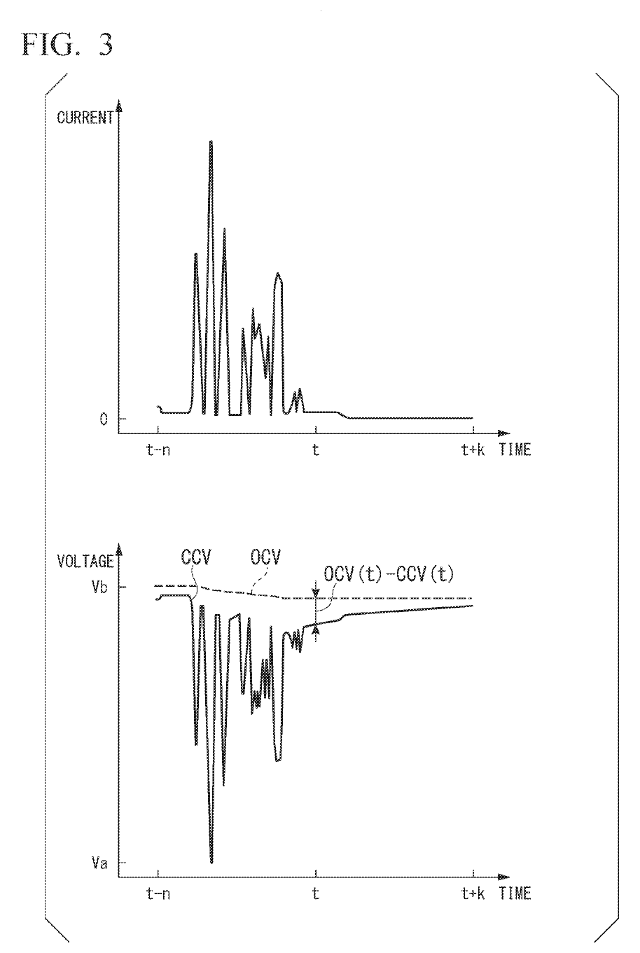

FIG. 3 is a view showing an example of a correspondence relationship between the open circuit voltage (OCV) and the closed circuit voltage (CCV) acquired by the OCV estimation portion 24 of the secondary battery state estimation device 10 of the embodiment.

As shown in FIG. 3, the open circuit voltage (OCV (t)) at the predetermined time t is obtained, for example, based on the data of the current and the closed circuit voltage (CCV) in a time zone from the time (t - n) to the time (t + k) including the predetermined time t.

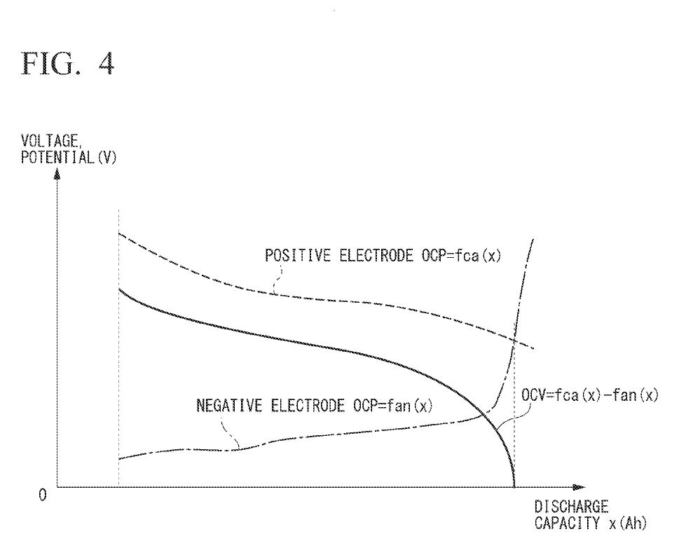

FIG. 4 is a view showing an example of an OCV curve acquired based on an OCP curve of each of a positive electrode and a negative electrode by the optimization portion 25 of the secondary battery state estimation device 10 in the embodiment.

As shown in FIG. 4, the optimization portion 25 acquires an OCP curve indicating a change in an open circuit potential (OCP) in accordance with a discharge capacity x (Ah) of each of the positive electrode and the negative electrode of the secondary battery 11, for example, based on a plurality of parameters relating to the state of the secondary battery 11. The optimization portion 25 acquires a positive electrode OCP curve (= fca (x)) and a negative electrode OCP curve (= fan (x)), for example, by causing a plurality of parameters to act on an OCP curve (reference OCP curve) stored in advance in the storage portion 21.

The reference OCP curve stored in the storage portion 21 is acquired, for example, by a test that is performed in advance, a simulation by an appropriate model, or the like. The reference OCP curve is, for example, an OCP curve of a simple substance of each active material constituting each of the positive electrode and the negative electrode of the secondary battery 11. The optimization portion 25 estimates the OCV curve (= fca (x) - fan (x)) indicating the change in the open circuit voltage (OCV) in accordance with the discharge capacity x (Ah), for example, based on the difference between the positive electrode OCP curve (= fca (x)) and the negative electrode OCP curve (= fan (x)).

The optimization portion 25 optimizes (reconfigures) a plurality of parameters relating to the state of the secondary battery 11, for example, based on history data by the open circuit voltage (OCV (t)) at the predetermined time t acquired by the OCV estimation portion 24 and the OCV curve estimated based on the OCP curve.

The optimization portion 25 performs a predetermined optimization process, for example, based on an error function indicating an error between the estimated OCV curve and the history data of the secondary battery 11. The error function is, for example, a weighted mean square error (Weighted RMSE), a weighted mean absolute error (Weighted MAE), or the like. The predetermined optimization process is, for example, a local optimization algorithm such as a BFGS method, a conjugate gradient method, and a COBYLA method, a global optimization algorithm such as a genetic algorithm, a differential evolution method, a SHGO method, and an annealing method, or the like. In a series of processes including the predetermined optimization process, for example, reconfiguring of the plurality of parameters by the optimization portion 25, acquisition of the positive electrode OCP curve and the negative electrode OCP curve, and estimation of the OCV curve are repeated so that the value of the error function becomes equal to or less than a predetermined value.

The history data of the open circuit voltage (OCV (t)) is, for example, data acquired in an appropriate period and is not limited to a series of data such as time series data.

The diagnosis portion 26 acquires a diagnosis value relating to the degradation state of the secondary battery 11, for example, based on the OCV curve estimated based on the OCP curve after the optimization of the plurality of parameters by the optimization portion 25. The diagnosis portion 26 sets the ratio of a full charge capacity at the time of degradation as a SOH (State Of Health) diagnosis value, for example, assuming that the full charge capacity in the initial state of the secondary battery 11 is 100 %. The full charge capacity at the time of degradation is, for example, a difference between a discharge capacity at a full discharge voltage and a discharge capacity at a full charge voltage acquired based on the OCV curve.

The diagnosis portion 26 stores history data of the SOH diagnosis value in the storage portion 21, for example, by associating the acquired SOH diagnosis value with the date and time when the OCV curve is obtained by the optimization portion 25.

### (Operation of secondary battery state estimation device)

Hereinafter, an operation of the secondary battery state estimation device 10 of the embodiment, particularly a process of acquiring the open circuit voltage (OCV (t)) at the predetermined time t performed by the OCV estimation portion 24 is described.

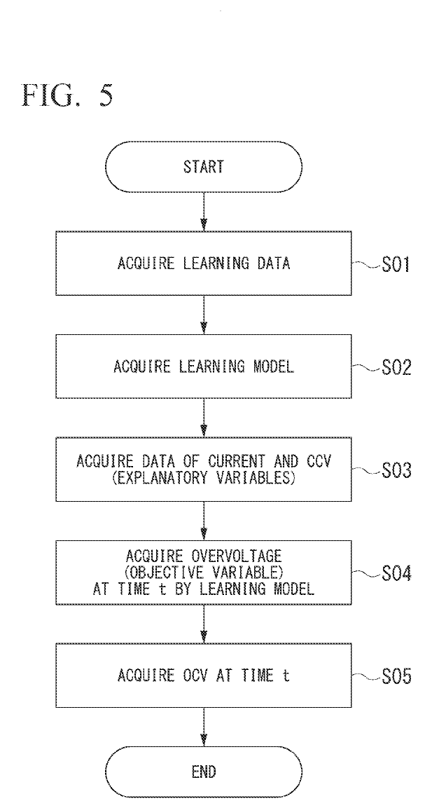

FIG. 5 is a flowchart showing a process performed by the secondary battery state estimation device 10 in the embodiment.

As shown in FIG. 5, first, the OCV estimation portion 24 acquires, for example, time series data of the current, the closed circuit voltage (CCV), and the open circuit voltage (OCV) of the secondary battery 11 as learning data for acquiring a machine learning model (Step S01, model acquisition step).

Next, the OCV estimation portion 24 acquires a machine learning model that outputs an overvoltage of the secondary battery 11 at an arbitrary time with respect to an input of the data of the current and the closed circuit voltage (CCV) at an appropriate time, for example, based on the acquired time series data (Step S02, model acquisition step).

Next, the OCV estimation portion 24 acquires, for example, data of the current and the closed circuit voltage (CCV) at an appropriate time which are explanatory variables input to the machine learning model, for example (Step S03, voltage estimation step).

Next, the OCV estimation portion 24 acquires an overvoltage at a predetermined time t which is an objective variable, for example, by an input of the explanatory variable to the machine learning model (Step S04, voltage estimation step).

Next, the OCV estimation portion 24 acquires the open circuit voltage (OCV (t)) at the predetermined time t, for example, by adding the overvoltage at the predetermined time t output from the machine learning model to the closed circuit voltage (CCV (t)) at the predetermined time t which is the explanatory variable (Step S05, voltage estimation step). Then, the OCV estimation portion 24 advances the process to the end.

As described above, according to the system 1 including the secondary battery state estimation device 10 of the embodiment, by using the machine learning model that outputs the overvoltage in accordance with the input of the data of the current and the closed circuit voltage (CCV), it is possible to prevent the decrease in the estimation accuracy of the internal state of the secondary battery 11, for example, even when the overvoltage increases in association with the increase in the internal resistance due to the degradation of the secondary battery 11. The shape change of the OCV curve in association with the degradation of the secondary battery 11 is reflected in the closed circuit voltage (CCV) detected in the secondary battery 11, and thereby, it is possible to improve the estimation accuracy of the open circuit voltage (OCV), for example, with respect to a variety of degradation modes without being limited to a specific degradation mode.

The explanatory variable is data in a time series, and thereby, it is possible to improve the estimation accuracy of the open circuit voltage (OCV) by the machine learning model.

It is possible to estimate the open circuit voltage (OCV) by past data or future data from a predetermined time t which is a target, and it is possible to improve the versatility of the machine learning model.

It is possible to estimate the open circuit voltage (OCV) without requiring the data of the temperature for the explanatory variable, and, for example, even when the machine learning model is acquired only by the data before degradation of the secondary battery 11, it is possible to improve the estimation accuracy of the open circuit voltage (OCV) with respect to the secondary battery 11 after degradation.

### (Modification example)

Hereinafter, modification examples of the embodiment is described. The same parts as those in the embodiment described above are denoted by the same reference numerals, and descriptions thereof are omitted or simplified.

The above embodiment is described using an example in which the secondary battery state estimation device 10 is constituted of the server 3; however, the embodiment is not limited thereto. For example, at least one of the processes performed by the server 3 may be performed by the battery control portion 13 of the vehicle 2. That is, the secondary battery state estimation device 10 may be constituted of the server 3 and the battery control portion 13 or only of the battery control portion 13.

The above embodiment is described using an example in which the machine learning model of the OCV estimation portion 24 outputs the overvoltage at the predetermined time t which is the objective variable with respect to the input of the data of the current and the closed circuit voltage (CCV) at an appropriate time which are the explanatory variables; however, the embodiment is not limited thereto. For example, the machine learning model may output the open circuit voltage (OCV (t)) at the predetermined time t which is the objective variable.

The above embodiment is described using an example in which the machine learning model of the OCV estimation portion 24 uses the data of the current and the closed circuit voltage (CCV) as the explanatory variables; however, the embodiment is not limited thereto. For example, the machine learning model may use data of the temperature of the secondary battery 11 as the explanatory variable in addition to the current and the closed circuit voltage (CCV).

In the embodiment described above, a plurality of explanatory variables of the machine learning model may be data in time zones different from each other.

The above embodiment is described using an example in which the machine learning model is acquired by the OCV estimation portion 24; however, the embodiment is not limited thereto. For example, the machine learning model may be acquired by another device other than the OCV estimation portion 24 or the server 3 and may be then stored in the OCV estimation portion 24 or the storage portion 21 or of the server 3.

The above embodiment is described using an example in which the OCP curve and the OCV curve are changes of the open circuit potential (OCP) or the open circuit voltage (OCV) in accordance with the discharge capacity x (Ah); however, the embodiment is not limited thereto. For example, instead of the discharge capacity (Ah), a parameter relating to the capacity such as a remaining capacity (SOC: State of Charge) or a depth of discharge (DOD: Depth of Discharge) may be used.

A program for realizing all or some of the functions of the system 1 including the secondary battery state estimation device 10 in the present invention may be recorded in a computer-readable recording medium, the program recorded in the recording medium may be read into and executed by a computer system, and thereby, all or some of the processes performed by the system 1 may be performed. It is assumed that the term “computer system” used herein includes an OS or hardware such as peripherals. Further, it is also assumed that the term “computer system” includes a WWW system which includes a homepage-providing environment (or a display environment). Further, the term “computer-readable recording medium” refers to a portable medium such as a flexible disk, a magneto-optical disk, a ROM, and a CD-ROM and a storage device such as a hard disk embedded in the computer system. Further, it is also assumed that the term “computer-readable recording medium” includes a medium which holds a program for a given time such as a volatile memory (RAM) in the computer system which becomes a server or a client when a program is transmitted through a network such as the Internet or a communication line such as a telephone line.

Further, the program may be transmitted from the computer system which stores the program in the storage device or the like to another computer system through a transmission medium or through transmission waves in the transmission medium. Here, the term “transmission medium” which transmits the program refers to a medium having a function of transmitting information that is, for example, a network (communication network) such as the Internet or a communication line such as a telephone line. Further, the program may be a program for realizing some of the above-described functions. Further, the program may be a so-called differential file (differential program) which can realize the above-described functions by a combination with a program already recorded in the computer system.

These embodiments of the present invention have been presented as examples and are not intended to limit the scope of the invention. These embodiments can be implemented in a variety of other modes, and various omissions, substitutions, and changes can be made without departing from the scope of the invention. These embodiments and modifications thereof are included in the scope and gist of the invention and are also included in the scope of the invention described in the appended claims and equivalent thereof.

What is claimed is:

1. A secondary battery state estimation system comprising:
a learning model that is structured so as to acquire first data having data in a time series of a current, a closed circuit voltage, and an open circuit voltage of a secondary battery in a predetermined state including at least one of charging and discharging and to output an open circuit voltage or an overvoltage which is a difference between the open circuit voltage and a closed circuit voltage of the secondary battery at an arbitrary time based on the first data; and
a voltage estimation portion that inputs second data having data of a current and a closed circuit voltage at a predetermined time detected in a secondary battery to be estimated to the learning model and thereby estimates an open circuit voltage or an overvoltage of the secondary battery to be estimated at an arbitrary time.

2. The secondary battery state estimation system according to claim 1,
wherein the second data has data in a time series of a current and a closed circuit voltage detected in the secondary battery to be estimated.

3. The secondary battery state estimation system according to claim 2,
wherein the voltage estimation portion inputs previous zone data having data of a current and a closed circuit voltage in a predetermined previous time zone before a predetermined time detected in the secondary battery to be estimated to the learning model and thereby estimates an open circuit voltage or an overvoltage of the secondary battery to be estimated at the predetermined time.

4. The secondary battery state estimation system according to claim 2,
wherein the voltage estimation portion inputs subsequent zone data having data of a current and a closed circuit voltage in a predetermined subsequent time zone after a predetermined time detected in the secondary battery to be estimated to the learning model and thereby estimates an open circuit voltage or an overvoltage of the secondary battery to be estimated at the predetermined time.

5. The secondary battery state estimation system according to claim 1,
wherein the second data does not have data relating to a temperature of the secondary battery to be estimated.

6. The secondary battery state estimation system according to claim 1,
wherein the learning model outputs the overvoltage of the secondary battery.

7. The secondary battery state estimation system according to claim 1,
wherein the learning model outputs an open circuit voltage of the secondary battery.

8. The secondary battery state estimation system according to claim 1,
wherein the first data has data in a time series of a current, a closed circuit voltage, and an open circuit voltage of the degraded secondary battery.

9. A secondary battery state estimation method performed by an electronic apparatus including a process portion that estimates an open circuit voltage or an overvoltage of a secondary battery to be estimated, the method including:
a model acquisition step of acquiring a learning model that acquires first data having data in a time series of a current, a closed circuit voltage, and an open circuit voltage of a secondary battery in a predetermined state including at least one of charging and discharging and that outputs an open circuit voltage or an overvoltage which is a difference between the open circuit voltage and a closed circuit voltage of the secondary battery at an arbitrary time based on the first data; and
a voltage estimation step of inputting second data having data of a current and a closed circuit voltage at a predetermined time detected in the secondary battery to be estimated to the learning model acquired by the model acquisition step and thereby estimating an open circuit voltage or an overvoltage of the secondary battery to be estimated at an arbitrary time.

10. A computer-readable non-transitory recording medium that records a program causing a computer of an electronic apparatus including a process portion that estimates an open circuit voltage or an overvoltage of a secondary battery to be estimated to execute:
a model acquisition step of acquiring a learning model that acquires first data having data in a time series of a current, a closed circuit voltage, and an open circuit voltage of a secondary battery in a predetermined state including at least one of charging and discharging and that outputs an open circuit voltage or an overvoltage which is a difference between the open circuit voltage and a closed circuit voltage of the secondary battery at an arbitrary time based on the first data; and
a voltage estimation step of inputting second data having data of a current and a closed circuit voltage at a predetermined time detected in the secondary battery to be estimated to the learning model acquired by the model acquisition step and thereby estimating an open circuit voltage or an overvoltage of the secondary battery to be estimated at an arbitrary time.
